(19) United States
(12) Patent Application Publication
(10) Pub. No.: US 2015/0287878 A1
(43) Pub. Date: Oct. 8, 2015

(54) SEMICONDUCTOR FILM, METHOD OF PRODUCING SEMICONDUCTOR FILM, SOLAR CELL, LIGHT-EMITTING DIODE, THIN FILM TRANSISTOR, AND ELECTRONIC DEVICE

(71) Applicant: FUJIFILM Corporation, Tokyo (JP)

(72) Inventors: Masashi ONO, Kanagawa (JP); Makoto KIKUCHI, Kanagawa (JP); Atsushi TANAKA, Kanagawa (JP); Masayuki SUZUKI, Kanagawa (JP); Yoshihiko KANEMITSU, Kyoto (JP)

(73) Assignee: FUJIFILM Corporation, Tokyo (JP)

(21) Appl. No.: 14/746,103

(22) Filed: Jun. 22, 2015

Related U.S. Application Data
(63) Continuation of application No. PCT/JP2013/082100, filed on Nov. 28, 2013.

(30) Foreign Application Priority Data
Dec. 26, 2012 (JP) 2012-282430

(51) Int. Cl. H01L 33/06; H01L 31/0352; H01L 31/0304; H01L 31/032; H01L 29/24; H01L 33/30; H01L 29/786; H01L 29/66; H01L 29/06; H01L 29/201; H01L 31/18; H01L 33/00

(52) U.S. Cl. CPC H01L 33/06; H01L 31/184; H01L 31/035218; H01L 31/0304; H01L 31/18; H01L 31/0324; H01L 33/0062; H01L 33/0091; H01L 33/30; H01L 29/78681; H01L 29/66742; H01L 29/66969; H01L 29/0665; H01L 29/201; H01L 29/245

(57) ABSTRACT

A semiconductor film, including: an assembly of semiconductor quantum dots containing a metal atom; a thiocyanate ion coordinated to the semiconductor quantum dots; and a metal ion.

### CROSS-REFERENCE TO RELATED APPLICATIONS

This application is a continuation application of International Application No. PCT/JP2013/082100, filed Nov. 28, 2013, the disclosure of which is incorporated herein by reference in its entirety. Further, this application claims priority from Japanese Patent Application No. 2012-282430, filed Dec. 26, 2012, the disclosure of which is incorporated herein by reference in its entirety.

### TECHNICAL FIELD

The present invention relates to a semiconductor film, a method of producing a semiconductor film, a solar cell, a light-emitting diode, a thin film transistor, and an electronic device.

### BACKGROUND ART

In recent years, the research on high efficiency solar cells called the third generation solar cells has flourished. Among others, solar cells using colloidal quantum dots have been reported to be, for example, capable of increasing the quantum efficiency as a result of a multi-exciton generation effect, and thus attention has been paid to them. However, in solar cells using colloidal quantum dots (also referred to as quantum dot solar cells), the conversion efficiency is about 7% at the maximum, and there is a demand for a further increase in the conversion efficiency.

In such a quantum dot solar cell, a semiconductor film formed from an assembly of quantum dots plays the role of a photoelectric conversion layer; therefore, research on semiconductor films themselves that are formed from a quantum dot assembly is also being conducted actively.

For example, semiconductor nanoparticles using a relatively long ligand having a hydrocarbon group having 6 or more carbon atoms have been disclosed (see, for example, Patent Document 1 (Japanese Patent No. 4425470)).

Regarding the technique for improving the characteristics of a semiconductor film formed from a quantum dot assembly, it has been reported that when the ligand molecule bound to a quantum dot (for example, about 2 nm to 10 nm) is replaced with a shorter ligand molecule, electrical conductivity is enhanced (see, for example, Non-Patent Document 1 (S. Geyer, et al., “Charge transport in mixed CdSe and CdTe colloidal nanocrystal films”, Physical Review B (2010)) and Non-Patent Document 2 (J. M. Luther, et al., “Structural, Optical, and Electrical Properties of Self-Assembled Films of PbSe Nanocrystals Treated with 1,2-Ethanedithiol”, ACS Nano (2008))). It has been reported in Non-Patent Document 2 that when the oleic acid (molecular chain length: about 2 nm to 3 nm) around the quantum dots of PbSe is replaced with ethanedithiol (molecular chain length: 1 nm or less), quantum dots are brought into close proximity to one another, and electrical conductivity is enhanced.

### SUMMARY OF INVENTION

### Technical Problem

However, since the semiconductor film described in Patent Document 1 has a large ligand, and the close proximity between semiconductor quantum dots is insufficient, excellent photoelectric conversion characteristics are not obtained. Even in a case in which the butylamine used in Non-Patent Document 1 or the ethanedithiol used in Non-Patent Document 2 is used as a ligand, for example, according to Non-Patent Document 1, a photoelectric current value of only about several hundred nanoamperes (nA) can be obtained at the maximum. Also, when ethanedithiol is used as a ligand, detachment of the semiconductor film may easily occur.

It is an object of the invention to provide a semiconductor film in which a high photoelectric current value is obtained and film detachment is suppressed, and a method of production thereof.

Furthermore, it is another object of the invention to provide a solar cell, a light-emitting diode, a thin film transistor and an electronic device, in each of which a high photoelectric current value is obtained and film detachment is suppressed.

### Solution to Problem

In order to achieve the above objects, the following invention is provided.

<1> A semiconductor film, comprising:
an assembly of semiconductor quantum dots containing a metal atom;
a thiocyanate ion coordinated to the semiconductor quantum dots; and
a metal ion.

<2> The semiconductor film according to <1>, wherein the metal ion is an alkali metal ion.

<3> The semiconductor film according to <2>, wherein the alkali metal ion is a potassium ion or a lithium ion.

<4> The semiconductor film according to any one of <1> to <3>, wherein the semiconductor quantum dots contain at least one selected from the group consisting of PbS, PbSe, InN, InAs, InSb, and InP.

<5> The semiconductor film according to any one of <1> to <4>, wherein the semiconductor quantum dots have an average particle diameter of from 2 nm to 15 nm.

<6> The semiconductor film according to any one of <1> to <5>, wherein the semiconductor quantum dots have an average shortest interdot distance of less than 0.45 nm.

<7> The semiconductor film according to any one of <4> to <6>, wherein the semiconductor quantum dots contain PbS.

<8> A method of producing a semiconductor film, the method comprising:
a semiconductor quantum dot assembly forming step of applying, onto a substrate, a semiconductor quantum dot dispersion liquid containing semiconductor quantum dots containing a metal atom, a first ligand coordinated to the semiconductor quantum dots, and a first solvent, and thereby forming an assembly of the semiconductor quantum dots; and
a ligand exchange step of applying, to the assembly, a ligand agent solution containing a second solvent and a second ligand agent that has a shorter molecular chain length than the first ligand and that includes a thiocyanate ion and a metal ion, and thereby exchanging the first ligand coordinated to the semiconductor quantum dots with the second ligand agent.

<9> The method of producing a semiconductor film according to <8>, wherein each of the semiconductor quantum dot assembly forming step and the ligand exchange step is carried out two or more times.

<10> The method of producing a semiconductor film according to <8> or <9>, wherein the second ligand agent is an alkali metal thiocyanate.

<11> The method of producing a semiconductor film according to <10>, wherein the second ligand agent is at least one of potassium thiocyanate or lithium thiocyanate.

<12> The method of producing a semiconductor film according to any one of <8> to <11>, wherein the semiconductor quantum dots contain at least one selected from the group consisting of PbS, PbSe, InN, InAs, InSb, and InP.

<13> The method of producing a semiconductor film according to any one of <8> to <12>, wherein the semiconductor quantum dots have an average particle diameter of from 2 nm to 15 nm.

<14> The method of producing a semiconductor film according to <12> or <13>, wherein the semiconductor quantum dots contain PbS.

<15> A solar cell, comprising the semiconductor film according to any one of <1> to <7>.

<16> A light-emitting diode, comprising the semiconductor film according to any one of <1> to <7>.

<17> A thin film transistor, comprising the semiconductor film according to any one of <1> to <7>.

<18> An electronic device, comprising the semiconductor film according to any one of <1> to <7>.

### Advantageous Effects Of Invention

According to the invention, a semiconductor film in which a high photoelectric current value is obtained and film detachment is suppressed, and a method of production thereof, are provided.

Furthermore, according to the invention, a solar cell, a light-emitting diode, a thin film transistor and an electronic device, in each of which a high photoelectric current value is obtained and film detachment is suppressed, are provided.

### BRIEF DESCRIPTION OF DRAWINGS

FIG. 1 is an outline diagram illustrating an example of the configuration of a p-n junction type solar cell to which the semiconductor film of the invention is applied.

FIG. 2 is an outline diagram illustrating a substrate with interdigitated electrodes used in the Examples.

FIG. 3 is an outline diagram illustrating the method of irradiating monochromatic light to a semiconductor film produced in the Examples.

FIG. 4 is an outline diagram illustrating the configuration of an experimental system used for the photoluminescence measurement in the Examples.

FIG. 5 is a diagram illustrating the results of photoluminescence measurement with respect to respective ligands.

### DESCRIPTION OF EMBODIMENTS

Hereinafter, the semiconductor film of the invention and a method of producing the same are described in detail. Meanwhile, in the present specification, “thiocyanate ion” is also called a “thiocyan group”.

<Semiconductor Film>

The semiconductor film of the invention comprises: an assembly of semiconductor quantum dots containing a metal atom; a thiocyanate ion coordinated to the semiconductor quantum dots; and a metal ion.

The semiconductor film of the invention contains at least an assembly of semiconductor quantum dots containing a metal atom; a thiocyanate ion; and a metal ion, and at least the thiocyanate ion is coordinated to the semiconductor quantum dots. When the semiconductor film has such a configuration, a high photoelectric current value is obtained, and film detachment is suppressed.

Semiconductor quantum dots are semiconductor particles configured to include a metal atom, and are nanometer-sized particles having a particle diameter of from several nanometers (nm) to several ten nanometers (nm).

It is contemplated that the S atom and N atom in the thiocyanate ion to be coordinated to the semiconductor quantum dots can easily form a coordinate bond with the cation moiety of the semiconductor quantum dots, and at the same time, the metal ion can easily form a coordinate bond with the anion moiety of the semiconductor quantum dots. Consequently, it is contemplated that the dangling bonds of both the cation moiety and the anion moiety are reduced, and as a result of a reduction of defects, overlapping of the wave functions between the semiconductor quantum dots can be intensified. As a result, it is believed that high electrical conductivity can be obtained.

The details of the method of producing a semiconductor film of the invention will be described below; and the semiconductor film of the invention can be obtained by adding, for example, a ligand agent containing at least a thiocyanate ion and a metal ion (also called a particular ligand agent) to an assembly of semiconductor quantum dots. The ligand agent is a compound having a ligand, and the particular ligand agent contains at least a thiocyanate ion as the ligand, and the thiocyanate ion is coordinated to the semiconductor quantum dots. The metal ion included in the particular ligand agent may also be bonded to the semiconductor quantum dots by coordinate bonding.

It is thought that in general organic ligands (ethanedithiol and the like), the coordinating group (SH, NH₂, OH, or the like) is coordinated only to the cation moiety at the surface of semiconductor quantum dots. Also, since the molecular chain length is longer compared with the thiocyanate ion, it is speculated that the amount of dangling bonds becomes large compared with the case of using the particular ligand agent containing a thiocyanate ion.

On the other hand, the particular ligand agent has at least a thiocyanate ion and a metal ion as described above.

An example of a general ligand agent having a thiocyanate ion is tetrabutylammonium thiocyanate (TBAT); however, when TBAT is coordinated to semiconductor quantum dots, sufficient electrical conductivity is not obtained. This is speculated to be because the molecular chain length of TBAT is long, the moiety of the tetrabutylammonium ion having a large molecular weight remains in the semiconductor film, and thus electrical conduction via semiconductor quantum dots is inhibited.

As such, since a thiocyanate ion has a short molecular chain length and has a S atom and a N atom that can be easily linked to semiconductor quantum dots by coordinate bonding, it is contemplated that thiocyanate ions are strongly coordinated to semiconductor quantum dots, the strength of the semiconductor film is increased, and film detachment is suppressed.

Hereinafter, the details of the various elements that constitute the semiconductor film of the invention will be described.

[Thiocyanate Ion and Metal Ion (Particular Ligand Agent)]

The semiconductor film of the invention has a thiocyanate ion and a metal ion.

The origins of the thiocyanate ion and the metal ion included in the semiconductor film of the invention are not particularly limited. The metal ion may be a monovalent metal ion, or may be a divalent or higher-valent metal ion. Furthermore, the metal ion may be an alkali metal ion, an alkaline earth metal ion, or a transition metal ion. Among the above-described ions, the metal ion is preferably an alkali metal ion, and potassium ion or lithium ion is preferred.

The semiconductor film of the invention may contain only one kind of metal ion, or may contain two or more kinds in mixture.

As described above, the semiconductor film of the invention can be obtained by adding, for example, a ligand agent containing at least a thiocyanate ion and a metal ion (particular ligand agent) to an assembly of semiconductor quantum dots.

Examples of the ligand agent containing at least a thiocyanate ion and a metal ion (particular ligand agent) include potassium thiocyanate, barium thiocyanate, mercury bisthiocyanate, calcium thiocyanate, cadmium thiocyanate, copper thiocyanate, lithium thiocyanate, silver thiocyanate, cobalt thiocyanate, lead bisthiocyanate, nickel thiocyanate, sodium thiocyanate, zinc thiocyanate, thallium thiocyanate, strontium thiocyanate, aluminum tris(thiocyanate), iron bis(thiocyanate), iron tris(thiocyanate), manganese bisthiocyanate, oxozirconium bis(thiocyanate), and oxohafnium bis(thiocyanate).

[Assembly of Semiconductor Quantum Dots Containing Metal Atom]

The semiconductor film of the invention includes an assembly of semiconductor quantum dots. Also, the semiconductor quantum dots contain at least one kind of metal atom.

An assembly of semiconductor quantum dots refers to a form in which a large number (for example, 100 or more quantum dots in a 1-μm² square) of semiconductor quantum dots are disposed closely to one another.

The term “semiconductor” according to the invention means a substance having a specific resistance value of from 10⁻² Ωcm to 10⁸ Ωcm.

Semiconductor quantum dots are semiconductor particles having metal atoms. According to the invention, examples of metal atoms also include semi-metal atoms such as a silicon (Si) atom.

Examples of the semiconductor quantum dot material that constitutes the semiconductor quantum dots include nanoparticles (particles having a size of 0.5 nm or more but less than 100 nm) of general semiconductor crystals [(a) Group IV semiconductors, (b) Group IV-IV, Group III-V, or Group II-VI compound semiconductors, and (c) compound semiconductors including combinations of three or more of Group II, Group III, Group IV, Group V, and Group VI elements]. Specific examples include semiconductor materials having relatively narrow band gaps, such as PbS, PbSe, InN, InAs, Ge, InAs, InGaAs, CuInS, CuInSe, CuInGaSe, InSb, Si, and InP.

The semiconductor quantum dots may contain at least one kind of the semiconductor quantum dot materials.

It is desirable for the semiconductor quantum dot material that the band gap in a bulk state is 1.5 eV or less. When such a semiconductor material having a relatively narrow band gap is used, high conversion efficiency can be realized in a case in which the semiconductor film of the invention is used in a photoelectric conversion layer of a solar cell.

A semiconductor quantum dot may have a core-shell structure which has a core made of a semiconductor quantum dot material and has the semiconductor quantum dot material covered with a coating compound. Examples of the coating compound include ZnS, ZnSe, ZnTe, and ZnCdS.

Among the materials described above, the semiconductor quantum dot material is desirably PbS or PbSe, in view of the ease of synthesis of semiconductor quantum dots. From the viewpoint of having less environmental burden, it is also desirable to use InN.

In the case of applying the semiconductor film of the invention to solar cell applications, it is preferable for the semiconductor quantum dots to have a narrower band gap in anticipation of an increase in the photoelectric conversion efficiency caused by a multiple exciton generation effect, which is also called a multi-exciton generation effect. Specifically, the band gap is desirably 1.0 eV or less.

From the viewpoint of further narrowing the band gap and enhancing the multi-exciton generation effect, the semiconductor quantum dot material is preferably PbS, PbSe, or InSb.

The average particle diameter of the semiconductor quantum dots is desirably from 2 nm to 15 nm. Meanwhile, the average particle diameter of the semiconductor quantum dots means the average particle diameter of ten semiconductor quantum dots. Transmission electron microscopy may be used for the measurement of the particle diameter of the semiconductor quantum dots. The “average particle diameter” of semiconductor quantum dots used herein refers to a number average particle diameter unless otherwise specified. That is, the number average particle diameter of the semiconductor quantum dots is desirably from 2 nm to 15 nm.

Generally, semiconductor quantum dots include particles of various sizes ranging from several nanometers (nm) to several ten nanometers (nm). In regard to semiconductor quantum dots, when the average particle diameter of quantum dots is decreased to a size less than or equal to the Bohr radius of the intrinsic electron, there occurs a phenomenon in which the band gap of the semiconductor quantum dots is changed by the quantum size effect. For example, Group II-VI semiconductors have relatively large Bohr radii, and the Bohr radius of PbS is said to be about 18 nm. Furthermore, the Bohr radius of InP, which is a Group III-V semiconductor, is said to be about from 10 nm to 14 nm.

Therefore, for example, when the average particle diameter of the semiconductor quantum dots is 15 nm or less, control of the band gap by the quantum size effect is enabled.

Particularly, in the case of applying the semiconductor film of the invention to a solar cell, it is important to adjust the band gap to an optimum value by the quantum size effect, irrespective of the semiconductor quantum dot material. However, as the average particle diameter of the semiconductor quantum dots becomes smaller, the band gap increases; therefore, when the average particle diameter of the semiconductor quantum dots is 10 nm or less, greater changes in the band gap can be expected. Even if the semiconductor quantum dots are consequently narrow gap semiconductor quantum dots, since it is easier to adjust the band gap to a band gap optimal for the solar spectrum, it is more desirable that the size (number average particle diameter) of the quantum dots is 10 nm or less. Furthermore, when the average particle diameter of the semiconductor quantum dots is small, and significant quantum confinement occurs, there is an advantage that an increase in the multi-exciton generation effect can be expected.

On the other hand, the average particle diameter (number average particle diameter) of the semiconductor quantum dots is preferably 2 nm or more. When the average particle diameter of the semiconductor quantum dots is adjusted to 2 nm or more, the effect of quantum confinement does not become too strong, and an optimum value of the band gap may be easily obtained. Also, when the average particle diameter of the semiconductor quantum dots is adjusted to 2 nm or more, it can be made easier to control the crystal growth of the semiconductor quantum dots during the synthesis of the semiconductor quantum dots.

The semiconductor film of the invention is preferably such that the average shortest interdot distance of the semiconductor quantum dots is less than 0.45 nm.

In a film configured to contain semiconductor quantum dots, if the average shortest interdot distance of the semiconductor quantum dots is large, electrical conductivity is decreased, and thus the film becomes an insulating body. When the average shortest interdot distance of the semiconductor quantum dots is shortened, electrical conductivity is enhanced, and a semiconductor film having a high photoelectric current value is obtained.

When the semiconductor film is configured to include an assembly of semiconductor quantum dots containing a metal atom, a thiocyanate ion coordinated to the semiconductor quantum dots, and a metal ion, the average shortest interdot distance can be adjusted to less than 0.45 nm.

Here, the average shortest interdot distance of the semiconductor quantum dots refers to the average value of the shortest distances between the surface of a certain semiconductor quantum dot A and the surface of another semiconductor quantum dot B adjacent to the semiconductor quantum dot A (interdot shortest distances). More particularly, the average shortest interdot distance is calculated as follows.

The interdot shortest distance of the semiconductor quantum dots can be obtained by evaluating the structure of a quantum dot film containing semiconductor quantum dots by a grazing incidence small angle X-ray scattering method (GISAXS). The center-to-center distance d between adjacent semiconductor quantum dots can be obtained by such a measurement, and the interdot shortest distance is calculated by subtracting the particle diameter of a semiconductor quantum dot from the center-to-center distance d thus obtained.

When a structure evaluation of a semiconductor film is carried out using a GISAXS measuring apparatus, the average of scattered X-rays with respect to the semiconductor quantum dots existing in the entire region irradiated with X-rays is detected as the scattered X-rays for the object of measurement. The interdot shortest distance calculated based on the detected scattered X-rays is the “average shortest interdot distance” as the average value of respective interdot shortest distances.

It is speculated that as the average shortest interdot distance of the semiconductor quantum dot is smaller, the photoelectric current value of the semiconductor film can be increased. However, with a form in which the average shortest interdot distance is 0 nm, that is, the semiconductor quantum dots are in contact with one another and aggregated, the features of nanometer-sized semiconductor quantum dots are not obtained, similarly to bulk semiconductor. Therefore, the average shortest interdot distance of the semiconductor quantum dots is preferably a size exceeding 0 nm.

The average shortest interdot distance of the semiconductor quantum dots is more preferably 0.44 nm or less, and still more preferably 0.43 nm or less.

The thickness of the semiconductor film is not particularly limited; however, from the viewpoint of obtaining high electrical conductivity, the thickness is preferably 10 nm or more, and more preferably 50 nm or more. Also, from the viewpoint that there is a risk of having an excessive carrier concentration, and from the viewpoint of the ease of production, the thickness of the semiconductor film is preferably 300 nm or less.

The method of producing a semiconductor film of the invention is not particularly limited; however, from the viewpoint of further shortening the distance between the semiconductor quantum dots and thereby closely arranging the semiconductor quantum dots, it is preferable to produce the semiconductor film by the method of producing a semiconductor film of the invention.

<Method of Producing Semiconductor Film>

A method of producing a semiconductor film of the invention comprises:
a semiconductor quantum dot assembly forming step of applying, onto a substrate, a semiconductor quantum dot dispersion liquid containing semiconductor quantum dots containing a metal atom, a first ligand coordinated to the semiconductor quantum dots, and a first solvent, and thereby forming an assembly of the semiconductor quantum dots; and
a ligand exchange step of applying, to the assembly, a ligand agent solution containing a second solvent and a second ligand agent that has a shorter molecular chain length than the first ligand and that includes a thiocyanate ion and a metal ion, and thereby exchanging the first ligand coordinated to the semiconductor quantum dots with the second ligand agent.

In the method of producing a semiconductor film of the invention, the semiconductor quantum dot assembly forming step and the ligand exchange step may be carried out repeatedly, and the method may further include a dispersion liquid drying step of drying a semiconductor quantum dot dispersion liquid, a solution drying step of drying a ligand agent solution, a washing step of washing the semiconductor quantum dot assembly on a substrate, and the like.

According to the method of producing a semiconductor film of the invention, in the semiconductor quantum dot assembly forming step, an assembly of semiconductor quantum dots is formed on a substrate by applying a semiconductor quantum dot dispersion liquid on a substrate. At this time, since the semiconductor quantum dots are dispersed in a first solvent by means of a first ligand having a longer molecular chain than a second ligand agent, the semiconductor quantum dots do not easily form an aggregated bulk form. Therefore, as the semiconductor quantum dot dispersion liquid is applied on a substrate, the assembly of semiconductor quantum dots can be configured such that the semiconductor quantum dots are individually arranged.

Next, a solution of a particular ligand agent is applied to the assembly of the semiconductor quantum dots in the ligand exchange step, and thereby ligand exchange between the first ligand coordinated to the semiconductor quantum dots and the second ligand agent having a shorter molecular chain length than the first ligand is achieved. Here, the second ligand agent is a ligand agent containing at least a thiocyanate ion and a metal ion, and is the particular ligand agent described above.

Through ligand exchange, the thiocyanate ion included in the particular ligand agent is coordinated to at least the metal atom included in the semiconductor quantum dots.

It is contemplated that through the ligand exchange step, the thiocyanate ion included in the second ligand agent (particular ligand agent) having a shorter molecular chain length than the first ligand is coordinated to the semiconductor quantum dots, instead of the first ligand, and is linked to the semiconductor quantum dots by coordinate bonding, and therefore, the semiconductor quantum dots can be easily brought into close proximity to each other. It is contemplated that as the semiconductor quantum dots are brought into close proximity, electrical conductivity of the assembly of the semiconductor quantum dots is increased, and a semiconductor film having a high photoelectric current value can be obtained.

[Semiconductor Quantum Dot Assembly Forming Step]

In the semiconductor quantum dot assembly forming step, a semiconductor quantum dot dispersion liquid containing semiconductor quantum dots, a first ligand coordinated to the semiconductor quantum dots, and a first solvent is applied onto a substrate, and thereby an assembly of semiconductor quantum dots is formed.

The semiconductor quantum dot dispersion liquid may be applied on the substrate surface, or may be applied on another layer provided on the substrate.

Examples of the other layer provided on the substrate include an adhesive layer for enhancing the adhesion between the substrate and the assembly of semiconductor quantum dots, and a transparent conductive layer.

Semiconductor Quantum Dot Dispersion Liquid

The semiconductor quantum dot dispersion liquid contains semiconductor quantum dots containing a metal atom, a first ligand, and a first solvent.

The semiconductor quantum dot dispersion liquid may further contain other components as long as the effects of the invention are not impaired.

(Semiconductor Quantum Dots)

The details of the semiconductor quantum dots containing a metal atom, which are included in the semiconductor quantum dot dispersion liquid, are the same as those described previously, and preferred aspects thereof are also the same.

The content of the semiconductor quantum dots in the semiconductor quantum dot dispersion liquid is preferably from 1 mg/ml to 100 mg/ml, and more preferably from 5 mg/ml to 40 mg/ml.

When the content of the semiconductor quantum dots in the semiconductor quantum dot dispersion liquid is 1 mg/ml or more, the semiconductor quantum dot density on the substrate is increased, and a satisfactory film may be easily obtained. On the other hand, when the content of the semiconductor quantum dots is 100 mg/ml or less, the film thickness of the film obtainable when the semiconductor quantum dot dispersion liquid is applied once is not likely to become large. Therefore, ligand exchange of the first ligand coordinated to the semiconductor quantum dots in the film can be carried out satisfactorily.

(First Ligand)

The first ligand contained in the semiconductor quantum dot dispersion liquid works as a ligand that is coordinated to the semiconductor quantum dots, and also accomplishes the role as a dispersant that disperses the semiconductor quantum dots in the first solvent because the first ligand has a molecular structure that is likely to provide steric hindrance.

The first ligand has a longer molecular chain length than the second ligand agent. Whether the molecular chain length is long or short is determined, in a case in which the molecule has a branched structure, based on the length of the main chain. Meanwhile, according to the present specification, the molecular chain length of the second ligand agent (particular ligand agent) means the chain length of the thiocyanate ion. The second ligand agent (particular ligand agent) is a compound having a thiocyanate ion and a metal ion as described above, and is unlikely to disperse semiconductor quantum dots in an organic solvent system. Here, dispersion refers to a state in which there is no sedimentation of particles or cloudiness.

From the viewpoint of enhancing the dispersion of the semiconductor quantum dots, the first ligand is desirably a ligand having a main chain having at least 6 or more carbon atoms, and more desirably a ligand having a main chain having at least 10 or more carbon atoms.

Specifically, the first ligand may be any of a saturated compound or an unsaturated compound, and examples thereof include decanoic acid, lauric acid, myristic acid, palmitic acid, stearic acid, behenic acid, oleic acid, erucic acid, oleylamine, dodecylamine, dodecanethiol, 1,2-hexadecanethiol, trioctylphosphine oxide, and cetrimonium bromide.

It is preferable that the first ligand is not likely to remain in the film at the time of forming a semiconductor film.

Among the compounds described above, from the viewpoint of being not likely to remain in the semiconductor film while imparting dispersion stability to the semiconductor quantum dots, the first ligand is preferably at least one of oleic acid or oleylamine.

The content of the first ligand in the semiconductor quantum dot dispersion liquid is preferably from 10 mmol/l to 200 mmol/l relative to the total volume of the semiconductor quantum dot dispersion liquid.

(First Solvent)

The first solvent included in the semiconductor quantum dot dispersion liquid is not particularly limited; however, the first solvent is preferably a solvent which does not easily dissolve the semiconductor quantum dots, but can easily dissolve the first ligand. The first solvent is preferably an organic solvent, and specific examples include an alkane [n-hexane, n-octane or the like], benzene, and toluene.

The first solvent may be used singly, or in combination of two or more kinds thereof.

Among the solvents described above, the first solvent is preferably a solvent which is not likely to remain in the semiconductor film thus formed. If a solvent having a relatively lower boiling point is used, when a semiconductor film is finally obtained, the content of the residual organic materials therein can be suppressed.

Furthermore, a solvent having high wettability to the substrate is definitely preferable. For example, in the case of applying the semiconductor quantum dot dispersion liquid on a glass substrate, an alkane such as hexane or octane is more preferred.

The content of the first solvent in the semiconductor quantum dot dispersion liquid is preferably from 90% by mass to 98% by mass relative to the total mass of the semiconductor quantum dot dispersion liquid.

Substrate

The semiconductor quantum dot dispersion liquid is applied onto a substrate.

There are no particular limitations on the shape, structure, size and the like of the substrate, and the substrate may be appropriately selected according to the purpose. The structure of the substrate may be a single layer structure or may be a laminated structure. For example, substrates formed from inorganic materials such as glass and YSZ (yttria-stabilized zirconia), resins, resin composite materials, and the like can be used. Among them, a substrate formed from a resin or a resin composite material is preferred from the viewpoint of being lightweight and flexible.

Examples of the resin include synthetic resins such as polybutylene terephthalate, polyethylene terephthalate, polyethylene naphthalate, polybutylene naphthalate, polystyrene, polycarbonate, polysulfone, polyether sulfone, polyarylate, allyl diglycol carbonate, polyamide, polyimide, polyamideimide, polyether imide, polybenzazole, polyphenylene sulfide, polycycloolefin, norbornene resins, fluororesins such as polychlorotrifluoroethylene, liquid crystalline polymers, acrylic resins, epoxy resins, silicone resins, ionomer resins, cyanate resins, crosslinked fumaric acid diesters, cyclic polyolefins, aromatic ethers, maleimide olefins, cellulose, and episulfide compounds.

Examples of a composite material of an inorganic material and a resin include composite plastic materials of resins and the following inorganic materials. That is, examples thereof include composite plastic materials of resins and silicon oxide particles, composite plastic materials of resins and metal nanoparticles, composite plastic materials of resins and inorganic oxide nanoparticles, composite plastic materials of resins and inorganic nitride nanoparticles, composite plastic materials of resins and carbon fibers, composite plastic materials of resins and carbon nanotubes, composite plastic materials of resins and glass flakes, composite plastic materials of resins and glass fibers, composite plastic materials of resins and glass beads, composite plastic materials of resins and clay minerals, composite plastic materials of resins and particles having a mica-derived crystal structure, laminated plastic materials having at least one joint interface between a resin and a thin glass plate, and composite materials having at least one or more joint interface by alternately laminating inorganic layers and organic layers and having barrier performance.

A stainless steel substrate, a multilayer metal substrate obtained by laminating stainless steel and a metal of another kind, an aluminum substrate, an oxide coating-clad aluminum substrate having the insulation properties of the surface enhanced by subjecting an aluminum substrate to a surface oxidation treatment (for example, anodization treatment), and the like may also be used.

It is preferable that the substrate formed from a resin or a resin composite material (a resin substrate or a resin composite material substrate) is excellent in heat resistance, dimensional stability, solvent resistance, electrical insulating properties, processability, low gas permeability, low hygroscopicity, and the like. The resin substrate and the resin composite material substrate may include a gas barrier layer for preventing the penetration of moisture, oxygen and the like, an undercoat layer for enhancing flatness of the resin substrate or adhesiveness to a lower electrode, or the like.

Furthermore, a lower electrode, an insulating film or the like may also be provided on the substrate, and in that case, the semiconductor quantum dot dispersion liquid is applied on the lower electrode, insulating film or the like over the substrate.

The thickness of the substrate is not particularly limited, but the thickness is preferably from 50 μm to 1000 μm, and more preferably from 50 μm to 500 μm. When the thickness of the substrate is 50 μm or more, flatness of the substrate itself is enhanced, and when the thickness of the substrate is 1000 μm or less, flexibility of the substrate itself is enhanced so that it becomes easier to use the semiconductor film as a flexible semiconductor device.

The technique of applying the semiconductor quantum dot dispersion liquid on a substrate is not particularly limited, and examples thereof include a method of coating the semiconductor quantum dot dispersion liquid on the substrate, and a method of immersing the substrate in the semiconductor quantum dot dispersion liquid.

Regarding the method of coating the semiconductor quantum dot dispersion liquid on the substrate, more specifically, liquid phase methods such as a spin coating method, a dipping method, an inkjet method, a dispenser method, a screen printing method, a relief printing method, an intaglio printing method, and a spray coating method can be used.

Particularly, when an inkjet method, a dispenser method, a screen printing method, a relief printing method, and intaglio printing method are used, a coating film can be formed at any position on the substrate, and since a patterning process after film formation is unnecessary, the process cost can be reduced.

[Ligand Exchange Step]

In the ligand exchange step, a ligand agent solution containing a second solvent and a second ligand agent having a shorter molecular chain length than the first ligand and containing a thiocyanate ion and a metal ion is applied to the assembly of semiconductor quantum dots formed on the substrate by the semiconductor quantum dot assembly forming step, and thereby the first ligand coordinated to the semiconductor quantum dots is exchanged with the second ligand agent (particular ligand agent) contained in the ligand agent solution.

When the first ligand is exchanged with the second ligand agent (particular ligand agent), at least the thiocyanate ion among the constituent elements of the particular ligand agent is coordinated to the metal atom included in the semiconductor quantum dots. The thiocyanate ion is coordinated to the metal atom included in the semiconductor quantum dots by at least one of a S atom or a N atom present in the thiocyanate ion that is composed of three atoms. Since the size of the ligand is as small as three atoms, it is contemplated that the quantum dots can be easily brought into close proximity to each other compared with the case in which a ligand having a long molecular chain is coordinated.

Meanwhile, the metal ion contained in the particular ligand agent may be linked to an anion contained in the semiconductor quantum dots (for example, dangling bond sites such as a chalcogen and an oxygen atom) by coordinate bonding, or may be scattered as a counterion of the thiocyanate ion without being linked to an anion, or may exist as a free ion.

If the first ligand remains in the semiconductor film, there is a risk that shortening of the distance between the semiconductor quantum dots may be inhibited in a part of the semiconductor film. Therefore, from the viewpoint of suppressing the remaining of the first ligand, it is preferable that ligand exchange is achieved more rapidly in the ligand exchange step. According to the invention, it is contemplated that since the second ligand agent has a shorter molecular chain length compared with the first ligand, the second ligand agent has high diffusibility. Therefore, it is contemplated that at the time of ligand exchange, the second ligand agent rapidly spreads widely over the entire area of the assembly of the semiconductor quantum dots, and the ligand exchange from the first ligand to the second ligand can be easily achieved.

Ligand Agent Solution

The ligand agent solution contains at least a second ligand agent (particular ligand agent) and a second solvent.

The ligand agent solution may further include other components as long as the effects of the invention are not impaired.

(Second Ligand Agent)

The second ligand agent is the particular ligand agent described above, and the molecular chain length thereof is shorter than that of the first ligand. The technique of determining whether the molecular chain length of a ligand is long or short is as described in the explanation on the first ligand.

The details of the particular ligand agent are also as described above.

The content of the particular ligand agent in the ligand agent solution is preferably from 5 mmol/l to 200 mmol/l, and more preferably from 10 mmol/l to 100 mmol/l, relative to the total volume of the ligand agent solution.

(Second Solvent)

The second solvent included in the ligand agent solution is not particularly limited; however, a solvent which can easily dissolve the particular ligand agent is preferable.

Such a solvent is preferably an organic solvent having a high dielectric constant, and examples thereof include ethanol, acetone, methanol, acetonitrile, dimethylformamide, dimethyl sulfoxide, butanol, and propanol.

The second solvent may be used singly, or a mixed solvent including two or more kinds thereof in mixture may also be used.

Among the solvents described above, the second solvent is preferably a solvent which is not likely to remain in the semiconductor film thus formed. From the viewpoint of being easily dried and easily removed by washing, an alcohol having a low boiling point or an alkane is preferred, and methanol, ethanol, n-hexane, or n-octane is more preferred.

The second solvent is preferably a solvent which is not miscible with the first solvent, and for example when an alkane such as hexane or octane is used as the first solvent, it is preferable to use a polar solvent such as methanol or acetone as the second solvent.

The content of the second solvent in the ligand agent solution is the balance obtained after subtracting the content of the particular ligand agent from the total mass of the ligand agent solution.

The method of applying the ligand agent solution to the assembly of semiconductor quantum dots is the same as the technique of applying the semiconductor quantum dot dispersion liquid onto a substrate, and preferred aspects thereof are also the same.

The semiconductor quantum dot assembly forming step and the ligand exchange step may be carried out repeatedly. When the semiconductor quantum dot assembly forming step and the ligand exchange step are carried out repeatedly, the electrical conductivity of the semiconductor film containing the assembly of the semiconductor quantum dots to which the particular ligand agent is coordinated is increased, and the thickness of the semiconductor film can be increased.

Regarding the repetition of the semiconductor quantum dot assembly forming step and the ligand exchange step, the respective steps may be repeated separately and independently; however, it is preferable to repeat a cycle of performing the semiconductor quantum dot assembly forming step and then performing the ligand exchange step. When a set of the semiconductor quantum dot assembly forming step and the ligand exchange step is repeated, unevenness of the ligand exchange may be suppressed easily.

In a case in which the semiconductor quantum dot assembly forming step and the ligand exchange step are carried out repeatedly, it is preferable to carry out film drying sufficiently after each cycle.

As the ratio of exchange with the particular ligand agent is higher in the ligand exchange of the semiconductor quantum dot assembly, the photoelectric current value of the semiconductor film is expected to increase.

It is sufficient if the ligand exchange between the first ligand and the second ligand agent (particular ligand agent) of the semiconductor quantum dots is carried out in at least a portion of the semiconductor quantum dot assembly, and it is not necessarily the case that 100% (by number) of the first ligand is replaced by the particular ligand agent.

(Washing Step)

The method of producing a semiconductor film of the invention may include a washing step of washing the semiconductor quantum dot assembly on the substrate.

As the method includes a washing step, any ligand that is present in excess and any ligand that has been detached from the semiconductor quantum dots can be removed. Furthermore, any residual solvent and other impurities can be removed. Washing of the semiconductor quantum dot assembly may be carried out by pouring at least one of the first solvent or the second solvent on the assembly of semiconductor quantum dots, or a substrate having the semiconductor quantum dot assembly or a semiconductor film formed thereon may be immersed in at least one of the first solvent or the second solvent.

Washing by the washing step may be carried out after the semiconductor quantum dot assembly forming step, or may be carried out after the ligand exchange step. The washing may also be carried out after the repetition of the set of the semiconductor quantum dot assembly forming step and the ligand exchange step.

(Drying Step)

The method of producing a semiconductor film of the invention may include a drying step.

The drying step may be a dispersion liquid drying step of drying the solvent remaining in the semiconductor quantum dot assembly after the semiconductor quantum dot assembly forming step, or may be a solution drying step of drying the ligand agent solution after the ligand exchange step. Furthermore, the drying step may also be a comprehensive step that is carried out after repetition of the set of the semiconductor quantum dot assembly forming step and the ligand exchange step.

When the respective steps described above are carried out, a semiconductor film is produced on a substrate.

The semiconductor film thus obtained has high electrical conductivity because the semiconductor quantum dots are brought into close proximity to one another by a particular ligand agent that is shorter than the conventional ligands, and a high photoelectric current value can be obtained. Also, since the particular ligand agent has a high complex stability constant, the semiconductor film of the invention constituted by semiconductor quantum dots and a particular ligand agent has stabilized coordinate bonding, and has excellent strength. Thus, detachment of the semiconductor film is also suppressed.

<Electronic Device>

The use of the semiconductor film of the invention is not limited; however, since the semiconductor film of the invention has photoelectric conversion characteristics and is not easily detached, the semiconductor film can be suitably applied to various electronic devices having semiconductor films or photoelectric conversion films.

Specifically, the semiconductor film of the invention can be suitably applied to the photoelectric conversion films of solar cells, light-emitting diodes (LEDs), semiconductor layers (active layers) of thin film transistors, photoelectric conversion films of indirect type radiation image pickup apparatuses, photodetectors for the visible-infrared regions, and the like.

<Solar Cell>

A solar cell is explained as an example of an electronic device including the semiconductor film of the invention, or a semiconductor film produced by the method of producing a semiconductor film of the invention.

For example, a p-n junction type solar cell can be produced using a semiconductor film device having a p-n junction, which includes a p-type semiconductor layer including the semiconductor film of the invention and an n-type semiconductor layer.

A more specific embodiment of the p-n junction type solar cell may be, for example, a form in which a p-type semiconductor layer and an n-type semiconductor layer are provided adjacently on a transparent conductive film formed on a transparent substrate, and a metal electrode is formed on the p-type semiconductor layer and the n-type semiconductor layer.

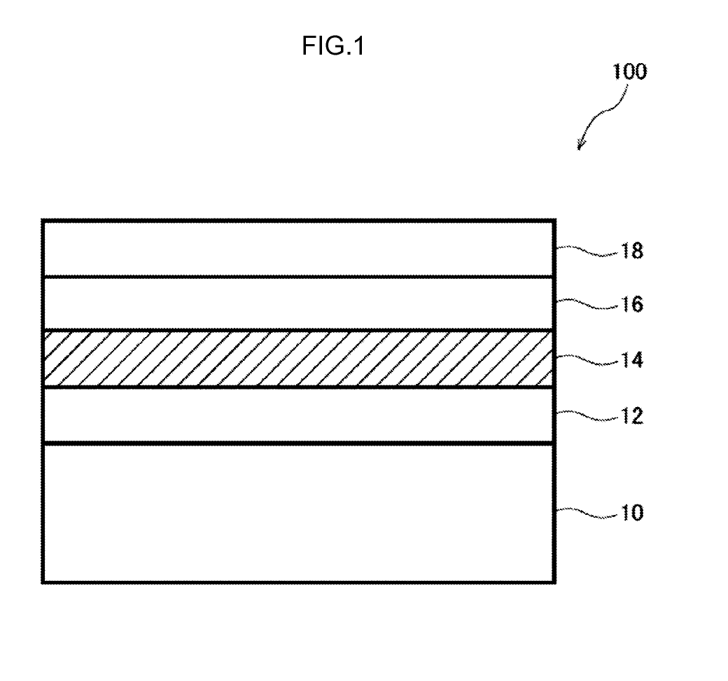

An example of the p-n junction type solar cell is described using FIG. 1.

FIG. 1 shows a schematic cross-sectional diagram of a p-n junction type solar cell 100 related to an embodiment of the invention. The p-n junction type solar cell 100 is configured to include a transparent substrate 10; a transparent conductive film 12 provided on the transparent substrate 10; a p-type semiconductor layer 14 composed of the semiconductor film of the invention on the transparent conductive film 12; an n-type semiconductor layer 16 on the p-type semiconductor layer 14; and a metal electrode 18 provided on the n-type semiconductor layer 16, all of which are laminated.

As the p-type semiconductor layer 14 and the n-type semiconductor layer 16 are laminated adjacently, the p-n junction type solar cell can be obtained.

Regarding the transparent substrate 10, the same material as that of the substrate used in the method of producing a semiconductor film of the invention can be used as long as the material is transparent. Specific examples include a glass substrate and a resin substrate. In this invention, examples of the transparent conductive film 12 include films composed of In₂O₃:Sn (ITO), SnO₂:Sb, SnO₂:F, ZnO:Al, ZnO:F, and CdSnO₄.

For the p-type semiconductor layer 14, the semiconductor film of the invention is used as described above.

Regarding the n-type semiconductor layer 16, a metal oxide is preferred. Specific examples include oxides of metals including at least one of Ti, Zn, Sn, or In, and more specific examples include TiO₂, ZnO, SnO₂, and IGZO. It is preferable that the n-type semiconductor layer is formed by a wet method (also called a liquid phase method), similarly to the p-type semiconductor layer, from the viewpoint of the production cost. Regarding the metal electrode 18, Pt, Al, Cu, Ti, Ni, and the like can be used.

### EXAMPLES

Hereinafter, the invention is explained by way of Examples, but the invention is not intended to be limited to these Examples.

<Production of Semiconductor Film Device>

[Preparation of Semiconductor Quantum Dot Dispersion Liquid 1]

First, a PbS particle dispersion liquid in which PbS particles were dispersed in toluene was prepared. For the PbS particle dispersion liquid, PbS CORE EVIDOT (nominal particle diameter: 3.3 nm, 20 mg/ml, solvent: toluene) manufactured by Evident Technologies, Inc. was used.

Subsequently, 2 ml of the PbS particle dispersion liquid was introduced into a centrifuge tube, 38 μl of oleic acid was added thereto, and then 20 ml of toluene was added thereto to decrease the concentration of the dispersion liquid. Thereafter, the PbS particle dispersion liquid was subjected to ultrasonic dispersion, and the PbS particle dispersion liquid was thoroughly stirred. Subsequently, 40 ml of ethanol was added to the PbS particle dispersion liquid, and the mixture was further subjected to ultrasonic dispersion and to centrifugation under the conditions of 10,000 rpm, 10 minutes, and 3° C. The supernatant in the centrifuge tube was discarded, subsequently 20 ml of octane was added to the centrifuge tube, and the mixture was subjected to ultrasonic dispersion. Precipitated quantum dots were thereby thoroughly dispersed in the octane. The dispersion thus obtained was subjected to concentration of the solution using a rotary evaporator (35 hpa, 40° C.). As a result, about 4 ml of a semiconductor quantum dot dispersion liquid 1 (octane solvent) having a concentration of approximately 10 mg/ml was obtained.

The particle diameter of the PbS particles contained in the semiconductor quantum dot dispersion liquid 1 was measured by STEM (Scanning transmission electron microscope) and analyzed by an image confirmation software, and the average particle diameter was 3.2 nm.

[Preparation of Semiconductor Quantum Dot Dispersion Liquid 2]

First, InP particles were synthesized, and an octane dispersion liquid of InP particles to which oleylamine was coordinated was prepared.

Preparation of Octane Dispersion Liquid of Oleylamine-Modified InP Particles

In a glove box, 30 ml of 1-octadecene, 1.81 ml of oleylamine, 0.60 g of anhydrous indium chloride, 0.49 ml of trisdimethylaminophosphine, and a magnetic stirrer were introduced into a three-necked round bottom flask in a N₂ gas atmosphere. Subsequently, the three-necked round bottom flask was taken out from the glove box in a state of being sealed with a stopper having a three-way valve, and the flask was placed in a magnetic stirrer-attached aluminum block thermostat bath. Thereafter, the three-way valve was operated, and the flask was purged with N₂ gas. While the mixture was vigorously stirred with the magnetic stirrer, heating of the aluminum block thermostat bath was started. The temperature of the aluminum block thermostat bath was increased up to 150° C. for about 30 minutes, and the temperature was maintained for 5 hours. Thereafter, heating was stopped, and the three-necked round bottom flask was cooled to room temperature using a blower fan.

The product was taken out from the three-necked round bottom flask, and unreacted materials and side products were removed by centrifugation using a centrifuge. The product (InP particles) was purified using ultra-dehydrated toluene as a good solvent and using dehydrated ethanol as a poor solvent. Specifically, a treatment of dissolving the product in the good solvent, redispersing the InP particle solution in the poor solvent, and centrifuging the InP particle dispersion liquid thus obtained, was repeated. For the redispersion, an ultrasonic cleaner was used. After the centrifugation of the InP particle dispersion liquid was repeated, the dehydrated ethanol remaining in the InP particle dispersion liquid was removed by distilling under reduced pressure using a rotary evaporator. Finally, the InP particles thus extracted were dispersed in octane, and thus an octane dispersion liquid having an oleylamine-modified InP particle concentration of 1 mg/ml was obtained. This was designated as a semiconductor quantum dot dispersion liquid 2.

The InP particles thus obtained were observed by STEM, and the particles were particles having an average particle diameter of about 4 nm.

[Preparation of Semiconductor Quantum Dot Dispersion Liquid 3]

In a three-necked flask, 30 ml of 1-octadecene, 6.32 mmol of lead(II) oxide, and 21.2 mmol of oleic acid were respectively weighed and mixed. The mixture was stirred with a magnetic stirrer at 300 rpm using an aluminum block hot plate stirrer. During the stirring of the mixture, degassing and dehydration were carried out in a vacuum at 120° C. for 1 hour. Subsequently, the three-necked flask was cooled to room temperature using a cooling fan, and purging with nitrogen gas was carried out. Subsequently, a solution containing 2.57 mmol of hexamethyldisilazane and 5 ml of 1-octadecene was injected into the three-necked flask using a syringe (injected by sticking the syringe needle into the septum cap). Thereafter, the three-necked flask was heated to 120° C. for 40 minutes and maintained for 1 minute, and then the three-necked flask was cooled to room temperature with a cooling fan. Unnecessary materials were removed from the product thus obtained, using a centrifuge, and only the PbS particles were extracted and dispersed in octane. When the unnecessary materials were removed from the product, toluene was used as a good solvent, and dehydrated ethanol was used as a poor solvent.

As a result of an observation using a STEM, it was found that the average particle diameter of the PbS thus obtained was 5 nm.

This octane dispersion liquid of PbS quantum dots was further diluted with a hexane solvent, and thereby a semiconductor quantum dot dispersion liquid 3 [mixed solvent of octane:hexane=1:9 (volume ratio)] having a concentration of approximately 10 mg/ml was obtained.

[Preparation of Ligand Agent Solution]

A ligand (agent) solution having a concentration of 0.1 mol/l was prepared by apportioning 1 mmol of the compound indicated in the column “Ligand (agent)” of Table 1 and dissolving the ligand (agent) in 10 ml of methanol. In order to accelerate dissolution of the ligand (agent) in the ligand (agent) solution, the ligand (agent) solution was irradiated with ultrasonic waves so that the ligand (agent) dissolved as much as possible and there was no residue.

[Substrate]

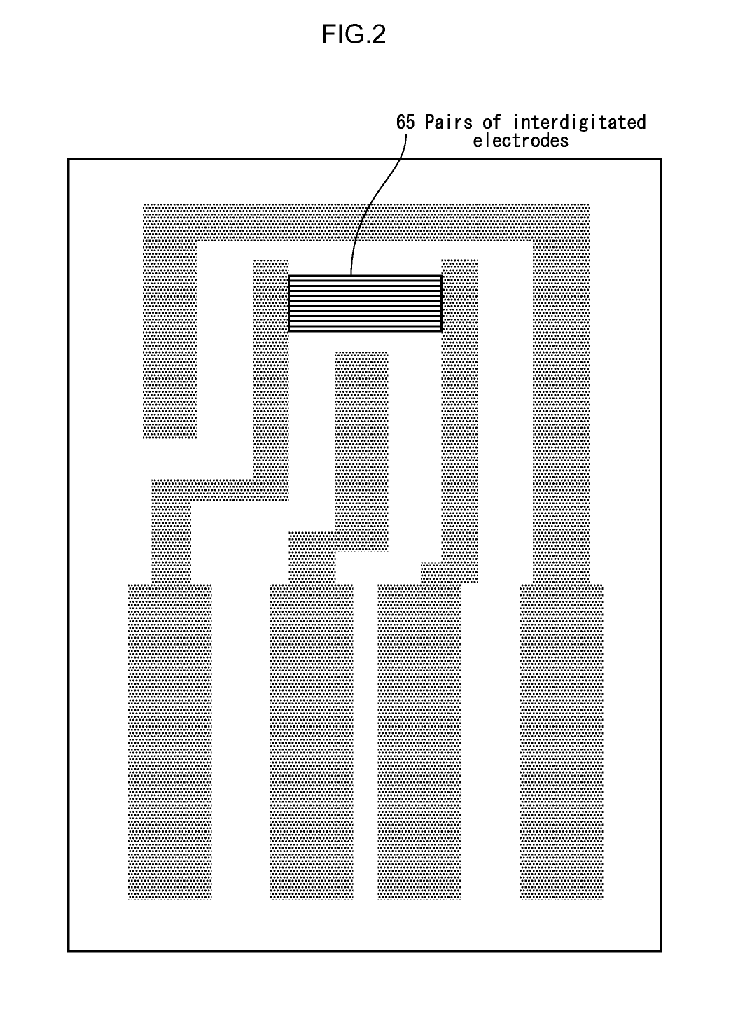

Regarding the substrate, a substrate having 65 pairs of interdigitated platinum electrodes illustrated in FIG. 2 on a quartz glass plate was prepared. For the interdigitated platinum electrodes, interdigitated electrodes manufactured by Bioanalytical Systems, Inc. (product No. 012126, electrode spacing: 5 μm) were used.

[Production of Semiconductor Film]

(1) Semiconductor Quantum Dot Assembly Forming Step

The semiconductor quantum dot dispersion liquid 1 or the semiconductor quantum dot dispersion liquid 2 thus prepared was dropped on a substrate, and then the dispersion liquid was spin coated at 2500 rpm. Thus, a semiconductor quantum dot assembly film was obtained.

(2) Ligand Exchange Step

Furthermore, a methanol solution of the ligand (agent) indicated in Table 1 [ligand (agent) solution] was dropped on the semiconductor quantum dot assembly film, and then the methanol solution was spin coated at 2500 rpm. Thus, a semiconductor film was obtained.

(3) Washing Step 1

Subsequently, only methanol, which was the solvent of the ligand (agent) solution, was dropped on the semiconductor film, and the solvent was spin coated.

(4) Washing Step 2

Furthermore, only an octane solvent was dropped on the semiconductor film after the washing by the washing step 1, and the octane solvent was spin coated.

The series of steps (1) to (4) were repeated for 15 cycles, and thereby a semiconductor film having a thickness of 100 nm, which was formed from an assembly of PbS quantum dots and had been subjected to ligand exchange, was obtained.

A semiconductor film device having a semiconductor film on a substrate was produced as described above.

The combinations of the semiconductor quantum dot dispersion liquids and the ligand (agent) solutions in the Examples and the Comparative Examples are as indicated in Table 1. In Table 1, “PbS” in the column “Kind” of the column “Semiconductor quantum dot” means that the semiconductor quantum dot dispersion liquid 1 was used, and “InP” means that the semiconductor quantum dot dispersion liquid 2 was used.

Furthermore, the kind of the ligand (agent) included in the ligand (agent) solution is the ligand (agent) indicated in the column “Kind” of the column “Ligand (agent)” of Table 1.

Regarding the compound indicated in “Ligand (agent)” of Table 1, the ligand agent used in Comparative Example 3 is potassium bromide (KBr), and the ligand agent used in Comparative Example 4 is cetyltrimethylammonium bromide [(CH₃(CH₂)₁₅N(CH₃)₃)⁺, Br⁻].

<Evaluation of Semiconductor Film>

The semiconductor films of the semiconductor film devices thus obtained were subjected to various evaluations.

1. Electrical Conductivity

An evaluation of the electrical conductivity of a semiconductor film was carried out by employing a semiconductor parameter analyzer for a semiconductor film device thus produced.

First, the voltage applied to the electrodes was scanned between −5 V and 5 V in a state that no light was irradiated to a semiconductor film device, and thus the I-V characteristics in a dark state were obtained. The electric current value in a state of having a bias of +5 V applied thereto was employed as the value of dark current, Id.

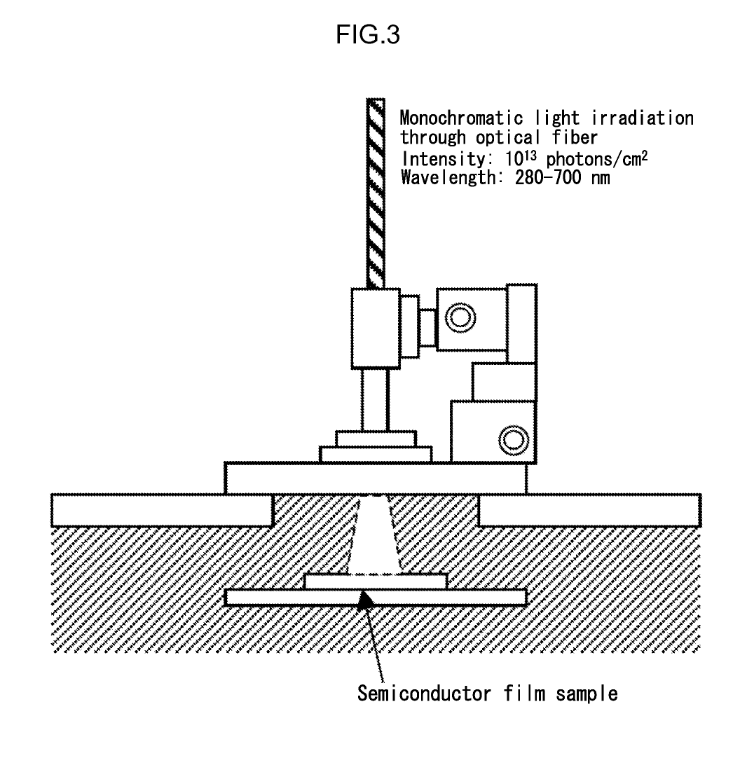

Next, the photoelectric current value in a state of having monochromatic light (irradiation intensity: 10¹³ photons) irradiated to the semiconductor film device was evaluated. The irradiation of monochromatic light to the semiconductor film device was carried out using the apparatus illustrated in FIG. 3. The wavelength of the monochromatic light was varied systematically between 280 nm and 700 nm. The increment of the electric current from the dark current in the case of irradiating light having a wavelength of 280 nm was designated as the photoelectric current value, Ip.

The evaluation results are presented in Table 1.

2. Film Detachment from Substrate

For the semiconductor film devices of the Examples and the Comparative Examples, detachment of the semiconductor films was evaluated by visual inspection. The presence or absence of film detachment is indicated in Table 1.

TABLE 1

| | | Semiconductor | | | | |
|---|---|---|---|---|---|---|
| | | quantum dots | | Electrical conductivity | | |
| | Ligand (agent) | | Average | | Dark | Presence or |
| | | | particle | Photoelectric | current | absence of |
| | Kind | Kind | diameter | current value Ip | value Id | film |
| | — | — | nm | A | A | detachment |
| Example 1 | Potassium thiocyanate | PbS | 3.2 | 5.29 × 10⁻⁵ | 3.10 × 10⁻⁴ | Absent |
| | (KSCN) | | | | | |
| Comparative | Ethanedithiol | PbS | 3.2 | 1.13 × 10⁻⁵ | 5.31 × 10⁻⁵ | Present |
| Example 1 | | | | | | |
| Comparative | Tetrabutylammonium | PbS | 3.2 | 9.65 × 10⁻⁷ | 8.12 × 10⁻⁷ | Absent |
| Example 2 | thiocyanate (TBAT) | | | | | |
| Comparative | KBr | PbS | 3.2 | 3.49 × 10⁻⁶ | 1.51 × 10⁻⁵ | Absent |
| Example 3 | | | | | | |
| Comparative | Cetyltrimethylammonium | PbS | 3.2 | 5.44 × 10⁻⁶ | 2.26 × 10⁻⁵ | Absent |
| Example 4 | bromide (CTAB) | | | | | |
| Example 2 | Potassium thiocyanate | InP | 4 | 1.15 × 10⁻¹¹ | 3.51 × 10⁻¹¹ | Absent |
| | (KSCN) | | | | | |
| Comparative | Ethanedithiol | InP | 4 | 2.24 × 10⁻¹³ | 4.24 × 10⁻¹² | Present |
| Example 5 | | | | | | |

As shown in Table 1, it was found that when a thiocyanate ion is coordinated to the semiconductor quantum dots while a metal ion is incorporated into the semiconductor film by subjecting the oleic acid ligand coordinated to the semiconductor quantum dots to ligand exchange, a high photoelectric current value and a high dark current value can be obtained compared with a conventional semiconductor film in which ethanedithiol is coordinated (Comparative Example 1).

Furthermore, in the semiconductor film in which ethanedithiol was coordinated, occurrence of conspicuous film detachment was recognized by visual inspection, while film detachment was not recognized in the semiconductor film devices of the Examples, and favorable roughness was realized.

It was found that, in a semiconductor film using TBAT that is a ligand agent including a thiocyanate ion similarly to the ligand agent of Example 1 but not including a metal ion (Comparative Example 2), the photoelectric current value and the dark current value were both markedly lowered. Therefore, it can be seen that a high photoelectric current value is not obtained only by the fact that the semiconductor film has a thiocyanate ion as a ligand. In this regard, it is speculated that since TBAT has a large counterion tetrabutylammonium [(C₄H₉)₄N⁺] unlike potassium thiocyanate, at the time of ligand exchange, it is difficult for the ligand agent to spread widely over the entire area of the assembly of semiconductor quantum dots, and the ligand agent interferes with bringing the semiconductor quantum dots into close proximity to one another. On the other hand, it is contemplated that since the cation included in the ligand agent of Example 1 is a smaller potassium ion, diffusibility at the time of ligand exchange is high, and it is unlikely to interfere with bringing the semiconductor quantum dots into close proximity to one another.

Therefore, when a metal thiocyanate is used as a ligand agent as shown in the invention, there is a possibility that electrical conductivity may be specifically high because the molecular chain length is shorter than the oleic acid ligand, and the metal ion can compensate the defects of dangling resulting from the anion of the quantum dots.

Furthermore, when a ligand agent containing a halogen atom, such as KBr or CTAB, is used as a low molecular weight (at an atomic level) ligand agent similar to potassium thiocyanate, as shown in Table 1, the semiconductor films of Comparative Examples 3 and 4 exhibited electrical conductivity that was not high. It is understood that as such, a semiconductor film can have the specifically increased electrical conductivity by using a metal thiocyanate.

3. Photoluminescence Spectrum of Semiconductor Quantum Dots

As can be seen from the evaluation results of the Examples and the Comparative Examples shown in Table 1, when the semiconductor quantum dots are brought into close proximity to one another using a particular ligand agent, electrical conductivity of the semiconductor film can be increased. However, on the other hand, if the semiconductor quantum dots are excessively brought into close proximity to one another, aggregation of the semiconductor quantum dots is likely to occur. It is anticipated that the semiconductor quantum dots exhibit the nature of a bulk state as a result of aggregation.

It is preferable that a semiconductor film maintains the properties of semiconductor quantum dots while exhibiting satisfactory electrical characteristics. Particularly, when it is contemplated to apply the semiconductor film to an LED or a solar cell, if the semiconductor film does not have the properties as semiconductor quantum dots, it is difficult to obtain the absorption or emission of an intended wavelength.

This can be determined from the peak wavelength of the PL (photoluminescence) spectrum for semiconductor quantum dots having a ligand.

Thus, a PL spectrum measurement of the semiconductor films according to Example 1 among the Examples, and Comparative Example 1 and Comparative Examples 3 and 4 among the Comparative Examples was carried out. For reference, the PL spectrum of a film of PbS semiconductor quantum dots to which oleic acid was coordinated without ligand exchange (Comparative Example 6) was also measured.

Here, the film of Comparative Example 6 is a film obtained by not conducting the steps (2) and (3) among the steps (1) to (4) for the “Production of semiconductor film” in Example 1. The film of Comparative Example 6 was an insulating film that did not exhibit electrical conductivity because the semiconductor quantum dots were not brought into close proximity to one another.

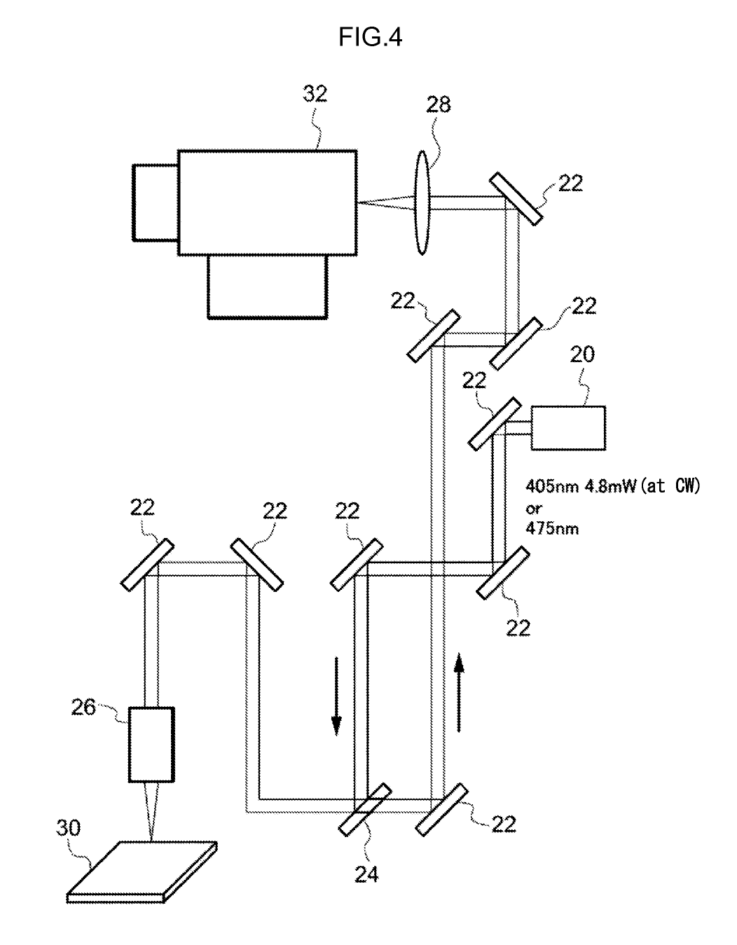

The configuration of the setting of the experimental system used for the photoluminescence measurement is schematically shown in FIG. 4. This experimental apparatus essentially includes a laser irradiator 20, a total reflection mirror 22, a dichroic mirror 24, lenses 26 and 28, and a spectrometer 32, and has a configuration in which laser light emitted from the laser irradiator 20 passes the total reflection mirror 22, the dichroic mirror 24, and the lenses 26 and 28 and reaches a measurement sample (semiconductor film of the device for evaluation) 30 and the spectrometer 32.

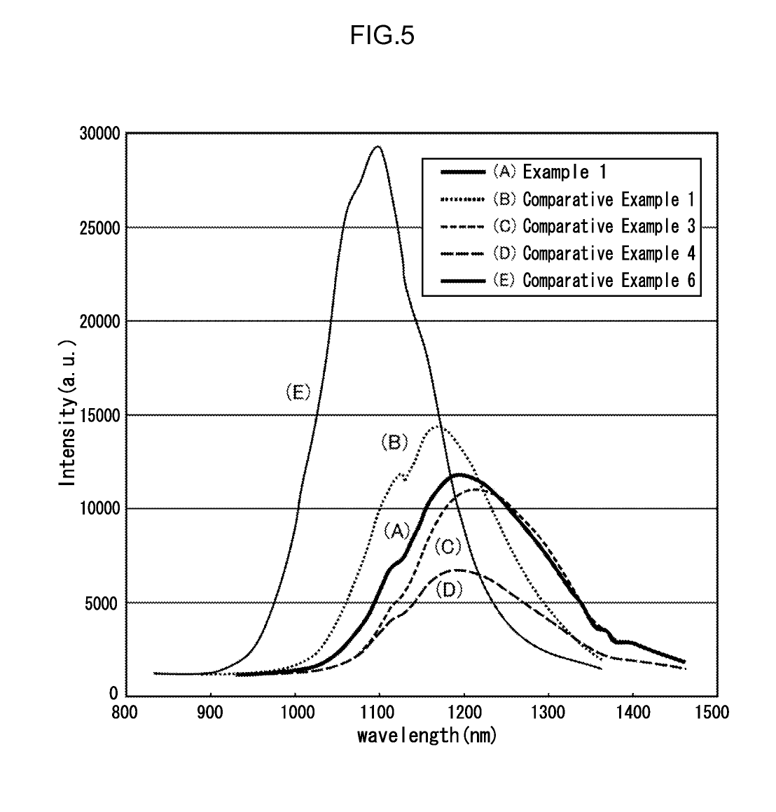

PL spectra are shown in FIG. 5. Also, the peak wavelengths for the respective ligands (ligand agents) are summarized in Table 2.

TABLE 2

| | | Peak wavelength | |
|---|---|---|---|
| | Ligand (agent) | (nm) | FIG. 5 |
| Example 1 | KSCN | 1199 | Curve (A) |
| Comparative Example 1 | Ethanedithiol | 1169 | Curve (B) |
| Comparative Example 3 | KBr | 1192 | Curve (C) |
| Comparative Example 4 | CTAB | 1216 | Curve (D) |
| Comparative Example 6 | Oleic acid (untreated) | 1097 | Curve (E) |

As can be seen from FIG. 5 and Table 2, the PbS semiconductor quantum dots that had not been subjected to ligand exchange and had oleic acid coordinated thereto (Comparative Example 6) had a peak wavelength of about 1100 nm. On the contrary, it is understood that in a semiconductor film that had been subjected to ligand exchange, such as the semiconductor film (Example 1), the peak wavelength was shifted to the longer wavelength side by about from 60 nm to 120 nm.

The shift of the peak wavelength to the longer wavelength side occurred because the confining potential of the semiconductor quantum dots was decreased as a result of bringing the semiconductor quantum dots into close proximity to one another by ligand exchange, and the band gap was effectively decreased. The largest decrement of the band gap was approximately 100 meV.

On the other hand, in the case of PbS in a bulk state, since the band gap is approximately 0.37 eV, and the photoluminescence peak exists at about 3350 nm, if quantum dots aggregate into a bulk-like state, the photoluminescence peak will appear at near this wavelength. Therefore, it was confirmed that the ligand-exchanged film of the invention has a decreased interdot distance and exhibits favorable conduction characteristics via quantum dots, while maintaining the properties (band gap and the like) of quantum dots.

Meanwhile, PbS in a bulk state is a common Group II-VI semiconductor, is single crystals of PbS, has a size larger than 100 nm, and is a semiconductor having no quantum size effect.

4. Average Shortest Interdot Distance between Semiconductor Quantum Dots in Semiconductor Film

First, respective quantum dot films (samples) of Example 3, Comparative Example 7, and Comparative Example 8 were produced as follows.

[Production of Semiconductor Film]

First, a hexamethyldisilazane solution was spin coated on a quartz glass plate, and hydrophobization of the surface was carried out. Then, a semiconductor film having an assembly of semiconductor quantum dots was prepared by the following procedure.

(I) Semiconductor Quantum Dot Assembly Forming Step

The semiconductor quantum dot dispersion liquid 3 prepared was drop cast onto a substrate, and thus a semiconductor quantum dot assembly film was obtained.

(II) Ligand Exchange Step

The semiconductor quantum dot assembly film was immersed for 3 minutes in a methanol solution of a ligand (agent) indicated in Table 3, and an exchange treatment from oleic acid as the first ligand to the ligand (agent) indicated in Table 3 was carried out. In this manner, quantum dot films of the Examples and the Comparative Examples were obtained.

(III) Washing Step i

Subsequently, each of the quantum dot films was immersed in a methanol solvent.

(IV) Washing Step ii

The quantum dot film obtained after the washing by the washing step i was further immersed in an octane solvent.

The series of steps (I) to (IV) were repeated for 2 cycles, and thus a semiconductor film having a thickness of 20 nm, which was composed of an assembly of PbS quantum dots and had been subjected to ligand exchange, was obtained.

In Comparative Example 8, a semiconductor quantum dot assembly film at the time point at which the (I) semiconductor quantum dot assembly forming step had been completed, was used.

For the quantum dot films (samples) of Example 3, Comparative Example 7, and Comparative Example 8 thus obtained, a structure evaluation was carried out by the grazing incidence small angle X-ray scattering (GISAXS) method. Detection of scattered light was carried out by using Kα radiation of Cu as the incident light, irradiating the quantum dot film with X-radiation at an incident angle slightly larger than the total reflection angle (approximately 0.4°), and scanning with the detector in the in-plane direction. Meanwhile, the detected scattered light is the average of scattered X-radiation for a sample existing over the entire region irradiated with X-radiation in the measurement apparatus.

Scattering peaks reflecting the in-plane periodic structure were obtained in all of the samples. Here, when a scattering peak position thus obtained is designated as θ_{MAX}, the center-to-center distance d between quantum dots is calculated by the following formula (D):

d=λ/2 sin θ_{MAX} (D).

In formula (D), λ represents the wavelength of the incident light.

The distances between adjacent quantum dots (distance obtained by subtracting the particle diameter of a quantum dot from the measured center-to-center distance d between quantum dots) as calculated from the scattering peaks are indicated in Table 3.

TABLE 3

| | | Average shortest |
|---|---|---|
| | Ligand (agent) | interdot distance |
| Example 3 | Potassium thiocyanate | 0.42 nm |
| Comparative Example 7 | Ethanedithiol | 0.45 nm |
| Comparative Example 8 | Oleic acid (untreated) | 1.31 nm |

From Table 3, it is understood that in all of the films that had been subjected to a ligand exchange treatment on the initial ligand (first ligand), oleic acid, the interdot distance was decreased. Particularly, in a potassium thiocyanate-treated film (semiconductor film containing potassium ions in the film and having coordinated thiocyanate ions), the distance between the semiconductor quantum dots was 0.42 nm, and it was confirmed that the dots were in closer proximity to one another compared with the conventional ethanedithiol-coordinated films.

From the results of this distance shortening between the semiconductor quantum dots and the results of measurement of electrical conduction presented in Table 1, it is contemplated that in the Examples of the invention, as the distance between the semiconductor quantum dots is decreased compared with conventional examples, the electronic interaction between quantum dots is enhanced, and consequently high electrical conduction characteristics are realized. In the Examples, prevention of film detachment is also realized.

All publications, patent applications, and technical standards mentioned in this specification are herein incorporated by reference to the same extent as if each individual publication, patent application, or technical standard was specifically and individually indicated to be incorporated by reference.

What is claimed is:

1. A semiconductor film, comprising:
an assembly of semiconductor quantum dots containing a metal atom;
a thiocyanate ion coordinated to the semiconductor quantum dots; and
a metal ion.

2. The semiconductor film according to claim 1, wherein the metal ion is an alkali metal ion.

3. The semiconductor film according to claim 2, wherein the alkali metal ion is a potassium ion or a lithium ion.

4. The semiconductor film according to claim 1, wherein the semiconductor quantum dots contain at least one selected from the group consisting of PbS, PbSe, InN, InAs, InSb, and InP.

5. The semiconductor film according to claim 1, wherein the semiconductor quantum dots have an average particle diameter of from 2 nm to 15 nm.

6. The semiconductor film according to claim 1, wherein the semiconductor quantum dots have an average shortest interdot distance of less than 0.45 nm.

7. The semiconductor film according to claim 4, wherein the semiconductor quantum dots contain PbS.

8. A method of producing a semiconductor film, the method comprising:
a semiconductor quantum dot assembly forming step of applying, onto a substrate, a semiconductor quantum dot dispersion liquid containing semiconductor quantum dots containing a metal atom, a first ligand coordinated to the semiconductor quantum dots, and a first solvent, and thereby forming an assembly of the semiconductor quantum dots; and
a ligand exchange step of applying, to the assembly, a ligand agent solution containing a second solvent and a second ligand agent that has a shorter molecular chain length than the first ligand and that includes a thiocyanate ion and a metal ion, and thereby exchanging the first ligand coordinated to the semiconductor quantum dots with the second ligand agent.

9. The method of producing a semiconductor film according to claim 8, wherein each of the semiconductor quantum dot assembly forming step and the ligand exchange step is carried out two or more times.

10. The method of producing a semiconductor film according to claim 8, wherein the second ligand agent is an alkali metal thiocyanate.

11. The method of producing a semiconductor film according to claim 10, wherein the second ligand agent is at least one of potassium thiocyanate or lithium thiocyanate.

12. The method of producing a semiconductor film according to claim 8, wherein the semiconductor quantum dots contain at least one selected from the group consisting of PbS, PbSe, InN, InAs, InSb, and InP.

13. The method of producing a semiconductor film according to claim 8, wherein the semiconductor quantum dots have an average particle diameter of from 2 nm to 15 nm.

14. The method of producing a semiconductor film according to claim 12, wherein the semiconductor quantum dots contain PbS.

15. A solar cell, comprising the semiconductor film according to claim 1.

16. A light-emitting diode, comprising the semiconductor film according to claim 1.

17. A thin film transistor, comprising the semiconductor film according to claim 1.

18. An electronic device, comprising the semiconductor film according to claim 1.
